(19) United States
(12) Patent Application Publication
(10) Pub. No.: US 2026/0005107 A1
(43) Pub. Date: Jan. 1, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Shinya NAKAGAWA, Fukuoka (JP); Toru KIYOHARA, Fukuoka (JP)

(73) Assignee: Mitsubishi Electric Corporation, Tokyo (JP)

(21) Appl. No.: 19/172,574

(22) Filed: Apr. 7, 2025

(30) Foreign Application Priority Data
Jul. 1, 2024 (JP) 2024-105976

(51) Int. Cl. H01L 23/495; H01L 21/48; H01L 23/31; H01L 23/373; H01L 25/07

(52) U.S. Cl. CPC H01L 23/49568; H01L 21/4878; H01L 23/3735; H01L 23/3107; H01L 25/072

(57) ABSTRACT

A semiconductor device includes: a heatsink, an insulating sheet, a frame disposed on the insulating sheet, semiconductor elements mounted on the frame; and the sealing material sealing the heatsink, the insulating sheet, the frame, and the semiconductor elements while a surface of the heatsink on a side opposite to a surface to which the insulating sheet is attached and a part of the frame are exposed. An extension part extending to an outer peripheral side is provided to a part of a side part of the heatsink on a side of a surface to which the insulating sheet is attached, and provided to the side part of the heatsink is a level difference including at least two stages of a first level difference concaved from the extension part to an inner peripheral side and a second level difference concaved further to an inner peripheral side.

### BACKGROUND

### Technical Field

The present disclosure relates to a semiconductor device and a method of manufacturing the semiconductor device.

### Description of the Background Art

Conventionally, in a transfer molding type semiconductor device having a structure in which an insulating sheet is attached on a heatsink, a level difference is provided to a part of a side part of the heatsink on a side of a surface opposite to a surface to which the insulating sheet is attached to firmly bond the heatsink and a sealing material and prevent ingress of moisture (for example, Japanese Patent Application Laid-Open No. 2002-314004).

### SUMMARY

In a technique described in Japanese Patent Application Laid-Open No. 2002-314004, the part of the side part of the side part of the heatsink on the side of the surface opposite to the surface to which the insulating sheet is attached and the sealing material can be firmly bonded by the level difference. However, when the side part of the heatsink and the sealing material are detached from each other, detachment proceeds by a reliability test, for example, and reaches an interface between the insulating sheet and the heatsink. As a result, there is a problem that insulation properties and heat radiation properties of the semiconductor device decreases.

An object of the present disclosure is to provide a technique capable of suppressing detachment of an insulating sheet and a heatsink in a semiconductor device.

A semiconductor device according to the present disclosure includes a heatsink, an insulating sheet, a frame, a semiconductor element, and a sealing material. The insulating sheet is attached on the heatsink. The frame is disposed on the insulating sheet. The semiconductor element is mounted on the frame. The sealing material seals the heatsink, the insulating sheet, the frame, and the semiconductor element while a surface of the heatsink on a side opposite to a surface to which the insulating sheet is attached and a part of the frame are exposed. An extension part extending to an outer peripheral side is provided to a part of a side part of the heatsink on a side of the surface to which the insulating sheet is attached. Provided to the side part of the heatsink is a level difference including at least two stages of a first level difference concaved from the extension part to an inner peripheral side and a second level difference concaved further to an inner peripheral side.

Since anchor effect is obtained by the level difference with at least two stages provided to the side part of the heatsink, detachment of the side part of the heatsink and the sealing material can be suppressed at an interface therebetween. As a result, detachment of the insulating sheet and the heatsink can also be suppressed. Even when detachment of the heatsink and the sealing material occurs, a distance of the interface between the side part of the heatsink and the sealing material increases by reason that the extension part is provided. Thus, it is possible to suppress the detachment reaching the interface between in insulating sheet and the heatsink.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to an embodiment 1.

FIG. 2 is an enlarged cross-sectional view illustrating a heatsink included in the semiconductor device according to the embodiment 1 and a surrounding part thereof.

FIG. 3 is a side view of the semiconductor device according to the embodiment 1.

FIG. 4 is a side view of a semiconductor device according to a modification example of the embodiment 1.

FIG. 5 is a side view for explaining a method of manufacturing the semiconductor device according to the embodiment 1.

FIG. 6 is an enlarged cross-sectional view illustrating a heatsink included in a semiconductor device according to an embodiment 2 and a surrounding part thereof.

### DESCRIPTION OF THE PREFERRED EMBODIMENTS

### Embodiment 1

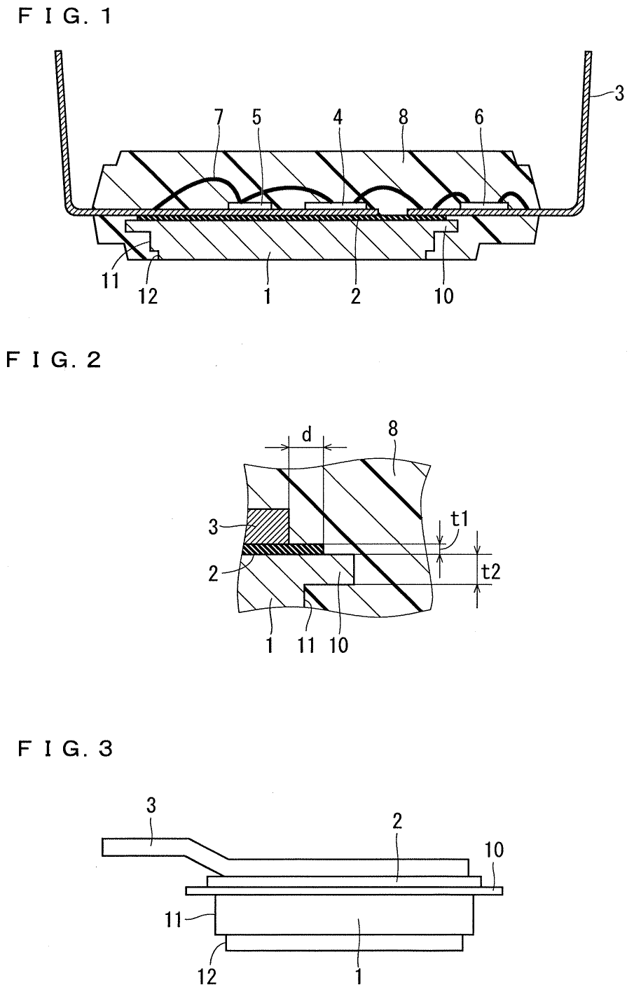

An embodiment 1 is described hereinafter using the diagrams. FIG. 1 is a cross-sectional view of the semiconductor device according to the embodiment 1. FIG. 2 is an enlarged cross-sectional view illustrating a heatsink 1 included in the semiconductor device according to the embodiment 1 and a surrounding part thereof.

As illustrated in FIG. 1, the semiconductor device is a transfer molding type intelligent power module (IPM), and includes the heatsink 1, an insulating sheet 2, a frame 3, semiconductor elements 4, 5, and 6, and a sealing material 8.

As illustrated in FIG. 1, the frame 3 is formed into a plate-like shape, and is disposed on the insulating sheet 2 attached on the heatsink 1.

The semiconductor elements 4, 5, and 6 are mounted on the frame 3 via a die bond material (not shown). The semiconductor element 4 is an insulated gate bipolar transistor (IGBT) or a metal-oxide-semiconductor field-effect transistor (MOSFET). The semiconductor element 5 is a diode. The semiconductor element 6 is a control integrated circuit (IC) controlling driving of the semiconductor elements 4 and 5.

A material constituting the semiconductor elements 4, 5, and 6 is silicon (Si), for example. A material constituting the semiconductor elements 4, 5, and 6 is not limited to silicon; however, also applicable is a wide bandgap semiconductor material such as silicon carbide (SiC), gallium nitride (GaN), or diamond (C), for example.

The semiconductor element 4 and the semiconductor element 5 are electrically connected to each other by the wire 7. The semiconductor element 4 and the semiconductor element 6 are electrically connected to each other by the wire 7. Each of semiconductor elements 4, 5, and 6 is electrically connected to the frame 3 by the wire 7. The wire 7 is aluminum (Al), for example. A material of the wire 7 is not limited to aluminum, but may be copper (Cu), gold (Au), or silver (Ag), for example.

The semiconductor element 4 and the semiconductor element 5 are power elements, heat is generated by driving the power element, and this heat is transmitted to the heatsink 1 via the insulating sheet 2. The insulating sheet 2 includes silica (SiO₂) or boron nitride (BN) as a main material to have heat radiation properties and insulation properties. As illustrated in FIG. 2, an appropriate thickness t1 of the insulating sheet 2 is set in consideration of the heat radiation properties, and is equal to or larger than 50 μm and equal to or smaller than 220 μm.

As illustrated in FIG. 1 and FIG. 2, the sealing material 8 is mold resin, for example. The sealing material 8 is formed by a transfer molding method, and seals the heatsink 1, the insulating sheet 2, the frame 3, and the semiconductor elements 4, 5, and 6 while a surface of the heatsink 1 on a side opposite to a surface to which the insulating sheet 2 is attached and a part of the frame 3 are exposed. The heatsink 1, the insulating sheet 2, the frame 3, and the semiconductor elements 4, 5, and 6 are insulated by the sealing material 8, and have a structure that functions of the insulating sheet 2 and the sealing material 8 do not significantly decrease in a reliability test mainly including a heat cycle test and a moisture resistance test.

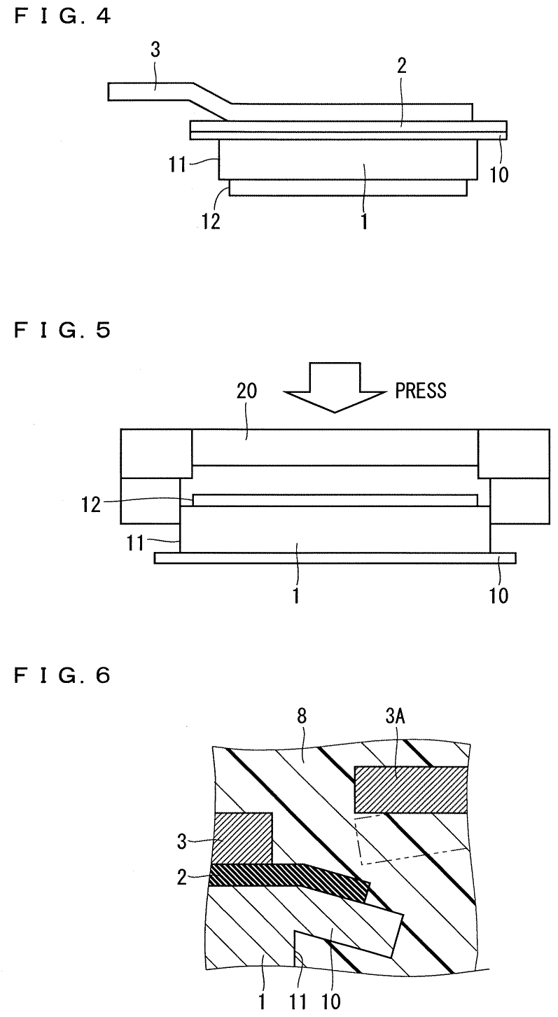

A structure of the heatsink 1 is described next. FIG. 3 is a side view of the semiconductor device according to the embodiment 1. FIG. 4 is a side view of a semiconductor device according to a modification example of the embodiment 1. The semiconductor elements 4, 5, and 6, the wire 7, and the sealing material 8 are omitted and the frame 3 is simplified so as to easily see the diagrams in FIG. 3 and FIG. 4.

A material constituting the heatsink 1 is copper (Cu), for example. An extension part 10 extending to an outer peripheral side is provided to a part of the side part of the heatsink 1 on a side of the surface to which the insulating sheet 2 is attached. A distance of an interface between the side part of the heatsink 1 and the sealing material 8 increases by reason that the extension part 10 is provided. Thus, it is suppressed that the detachment of the heatsink 1 and the sealing material 8 reaches the interface between the insulating sheet 2 and the heatsink 1.

A level difference with two stages of a first level difference 11 and a second level difference 12 is provided to the side part of the heatsink 1. The first level difference 11 is a level difference concaved from the extension part 10 to an inner peripheral side. The second level difference 12 is a level difference concaved from the first level difference 11 to a further inner peripheral side. In other words, the second level difference 12 is a level difference concaved from the surface of the heatsink 1 on the side opposite to the surface to which the insulating sheet 2 is attached to an inner peripheral side.

Since anchor effect is obtained by the level difference with two stages provided to the side part of the heatsink 1, detachment of the side part of the heatsink 1 and the sealing material 8 can be suppressed at the interface therebetween, and detachment of the insulating sheet 2 and the heatsink 1 is also suppressed. The level difference is not limited to include two stages; however, it is sufficient that the level difference includes at least two stages.

The extension part 10 extends closer to an outer peripheral side in relation to a peripheral edge part of the insulating sheet 2. As illustrated in FIG. 4, it is applicable that the extension part 10 does not extend from the peripheral edge part of the insulating sheet 2 to the outer peripheral side, but a shape of the extension part 10 in a top view is the same as the insulating sheet 2. In other words, an end surface of the extension part 10 and an end surface of the insulating sheet 2 may be located in the same position.

A thickness t2 of the extension part 10 is equal to or larger than the thickness t1 of the insulating sheet 2 and equal to or smaller than 0.8 mm. As described above, the thickness t1 of the insulating sheet 2 is equal to or larger than 50 μm and equal to or smaller than 220 μm; thus, the thickness t2 of the extension part 10 is equal to or larger than 50 μm and equal to or smaller than 0.8 mm. Since the thickness t2 of the extension part 10 is reduced, the extension part 10 is deformed in an up-down direction and stress can be reduced when a difference of the linear expansion coefficient occurs between the sealing material 8 and the heatsink 1.

Conventionally, a distance d from an end surface of the frame 3 to the end surface of the insulating sheet 2 is set large based on an assumption that the insulating sheet 2 and the heatsink 1 are detached. However, in the embodiment 1, the detachment of the insulating sheet 2 and the heatsink 1 can be suppressed; thus, the distance d from the end surface of the frame 3 to the end surface of the insulating sheet 2 is made small. Specifically, the distance d from the end surface of the frame 3 to the end surface of the insulating sheet 2 is equal to or smaller than 1 mm.

A method of manufacturing the semiconductor device according to the embodiment 1 is described next. FIG. 5 is a side view for explaining the method of manufacturing the semiconductor device according to the embodiment 1.

As illustrated in FIG. 5, performed is press processing of punching the heatsink 1 by a press mold 20 from the surface of the heatsink 1 on the side opposite to the surface to which the insulating sheet 2 is attached to form the level difference with two stages of the first level difference 11 and the second level difference 12 in the heatsink 1. The extension part 10 is also formed at the same time by this press processing. Although not shown in the diagrams, the insulating sheet 2 and the heatsink 1 after press processing are attached to each other to manufacture a heatsink with an integrated insulating sheet next. The frame 3 is disposed on the heatsink with the insulating sheet, the semiconductor elements 4, 5, and 6 are mounted on the frame 3, wire bonding is performed, and then transfer molding is performed. The semiconductor device according to the embodiment 1 is completed through these processes. The level difference formed by the press processing is not limited to include two stages; however, it is sufficient that the level difference includes at least two stages.

In the completed semiconductor device, stress occurs due to a difference of a linear expansion coefficient of each member when heat is applied; thus, the semiconductor device is designed to reduce this stress. Even in such a state, the insulating sheet 2 needs to ensure functions of insulation properties and heat radiation properties. Detachment of the insulating sheet 2 and the heatsink 1 is one of factors of losing these functions. With regard to this detachment, it is confirmed that detachment proceeds at the interface between the side part of the heatsink 1 and the sealing material 8, and this detachment reaches the interface between the insulating sheet 2 and the heatsink 1 to cause detachment thereof in addition to the state where the detachment of the insulating sheet 2 and the heatsink 1 occurs by stress due to the difference of the linear expansion coefficient of each member.

Accordingly, in the embodiment 1, the semiconductor device includes the heatsink 1, the insulating sheet 2 attached on the heatsink 1, the frame 3 disposed on the insulating sheet 2, the semiconductor elements 4, 5, and 6 mounted on the frame 3, and the sealing material 8 sealing the heatsink 1, the insulating sheet 2, the frame 3, and the semiconductor elements 4, 5, and 6 while the surface of the heatsink 1 on the side opposite to the surface to which the insulating sheet 2 is attached and a part of the frame 3 are exposed. The extension part 10 extending to the outer peripheral side is provided to a part of the side part of the heatsink 1 on the side of the surface to which the insulating sheet 2 is attached, and provided to the side part of the heatsink 1 is the level difference including at least two stages of the first level difference 11 concaved from the extension part 10 to the inner peripheral side and the second level difference 12 concaved further to an inner peripheral side.

Since anchor effect is obtained by the level difference with at least two stages provided to the side part of the heatsink 1, detachment of the side part of the heatsink 1 and the sealing material 8 can be suppressed at the interface therebetween. As a result, detachment of the insulating sheet 2 and the heatsink 1 can also be suppressed. Even when detachment of the heatsink 1 and the sealing material 8 occurs, the distance of the interface between the side part of the heatsink 1 and the sealing material 8 increases by reason that the extension part 10 is provided. Thus, it can be suppressed that the detachment thereof reaches the interface between the insulating sheet 2 and the heatsink 1.

In the process of attaching the insulating sheet 2 to the heatsink 1, applied is the design in which the insulating sheet 2 is also disposed on the extension part 10. Thus, the extension part 10 and the insulating sheet 2 can be pressure-bonded with further large force, and a surrounding part of the insulating sheet 2 which is easily detached can be firmly bonded.

The insulating sheet 2 includes silica or boron nitride as a main material, and the thickness t1 of the insulating sheet 2 is equal to or larger than 50 μm and equal to or smaller than 220 μm. Accordingly, heat radiation properties and insulation properties needed for the insulating sheet 2 can be ensured, and adhesiveness to the heatsink 1 can be improved.

The thickness t2 of the extension part 10 of the heatsink 1 is equal to or larger than the thickness of the insulating sheet 2 and equal to or smaller than 0.8 mm; thus, when the thickness t2 of the extension part 10 is reduced, the extension part 10 is deformed in the up-down direction and stress can be reduced when the difference of the linear expansion coefficient occurs between the sealing material 8 and the heatsink 1. As a result, detachment caused by the stress can be further suppressed in the extension part 10.

The distance d from the end surface of the frame 3 to the end surface of the insulating sheet 2 is equal to or smaller than 1 mm. Since the sizes of the heatsink 1 and the insulating sheet 2 can be reduced, cost of components can be reduced.

Since the level difference with at least two stages is formed by performing press processing of punching the heatsink 1 from the side of the surface on the side opposite to the surface to which the insulating sheet 2 is attached, the level difference with at least two stages can be easily formed.

### Embodiment 2

A semiconductor device according to an embodiment 2 is described next. FIG. 6 is an enlarged cross-sectional view illustrating the heatsink 1 included in the semiconductor device according to the embodiment 2 and a surrounding part thereof. In the description in the embodiment 2, the same reference numerals are assigned to the same constituent elements as those described in the embodiment 1, and the description thereof will be omitted.

As illustrated in FIG. 6, in the embodiment 2, the extension part 10 of the heatsink 1 is bended to a side opposite to the insulating sheet 2. In the similar manner, a part of the insulating sheet 2 attached to the extension part 10 is also bended in the same side.

Accordingly, as shown by a dashed-two dotted line in FIG. 6, even when a frame 3A as a different electrode is deformed and a distance from the frame 3A to the heatsink 1 is reduced, short circuit therebetween can be suppressed.

Each embodiment can be arbitrarily combined, or each embodiment can be appropriately varied or omitted.

The aspects of the present disclosure are collectively described hereinafter as appendixes.

### (Appendix 1)

A semiconductor device, comprising:
a heatsink;
an insulating sheet attached on the heatsink;
a frame disposed on the insulating sheet;
a semiconductor element mounted on the frame; and
a sealing material sealing the heatsink, the insulating sheet, the frame, and the semiconductor element while a surface of the heatsink on a side opposite to a surface to which the insulating sheet is attached and a part of the frame are exposed, wherein
an extension part extending to an outer peripheral side is provided to a part of a side part of the heatsink on a side of the surface to which the insulating sheet is attached, and
provided to the side part of the heatsink is a level difference including at least two stages of a first level difference concaved from the extension part to an inner peripheral side and a second level difference concaved further to an inner peripheral side.

### (Appendix 2)

The semiconductor device according to Appendix 1, wherein
the extension part extends closer to an outer peripheral side in relation to a peripheral edge part of the insulating sheet.

### (Appendix 3)

The semiconductor device according to Appendix 1 or 2, wherein
the insulating sheet includes silica or boron nitride as a main material, and
a thickness of the insulating sheet is equal to or larger than 50 μm and equal to or smaller than 220 μm.

### (Appendix 4)

The semiconductor device according to Appendix 3, wherein
a thickness of the extension part of the heatsink is equal to or larger than the thickness of the insulating sheet and equal to or smaller than 0.8 mm.

### (Appendix 5)

The semiconductor device according to any one of Appendixes 1 to 4, wherein
a distance from an end surface of the frame to an end surface of the insulating sheet is equal to or smaller than 1 mm.

### (Appendix 6)

The semiconductor device according to Appendix 4, wherein
the extension part of the heatsink is bended to a side opposite to the insulating sheet.

### (Appendix 7)

A method of manufacturing the semiconductor device according to any one of Appendixes 1 to 6, comprising
performing press processing of punching the heatsink from the side of the surface on the side opposite to the surface to which the insulating sheet is attached to form the level difference with the at least two stages.

While the disclosure has been shown and described in detail, the foregoing description is in all aspects illustrative and not restrictive. It is therefore understood that numerous modifications and variations can be devised.

What is claimed is:

1. A semiconductor device, comprising:
a heatsink;
an insulating sheet attached on the heatsink;
a frame disposed on the insulating sheet;
a semiconductor element mounted on the frame; and
a sealing material sealing the heatsink, the insulating sheet, the frame, and the semiconductor element while a surface of the heatsink on a side opposite to a surface to which the insulating sheet is attached and a part of the frame are exposed, wherein
an extension part extending to an outer peripheral side is provided to a part of a side part of the heatsink on a side of the surface to which the insulating sheet is attached, and
provided to the side part of the heatsink is a level difference including at least two stages of a first level difference concaved from the extension part to an inner peripheral side and a second level difference concaved further to an inner peripheral side.

2. The semiconductor device according to claim 1, wherein
the extension part extends closer to an outer peripheral side in relation to a peripheral edge part of the insulating sheet.

3. The semiconductor device according to claim 1, wherein
the insulating sheet includes silica or boron nitride as a main material, and
a thickness of the insulating sheet is equal to or larger than 50 μm and equal to or smaller than 220 μm.

4. The semiconductor device according to claim 3, wherein
a thickness of the extension part of the heatsink is equal to or larger than the thickness of the insulating sheet and equal to or smaller than 0.8 mm.

5. The semiconductor device according to claim 1, wherein
a distance from an end surface of the frame to an end surface of the insulating sheet is equal to or smaller than 1 mm.

6. The semiconductor device according to claim 4, wherein
the extension part of the heatsink is bended to a side opposite to the insulating sheet.

7. A method of manufacturing the semiconductor device according to claim 1, comprising
performing press processing of punching the heatsink from the side of the surface on the side opposite to the surface to which the insulating sheet is attached to form the level difference with the at least two stages.
